(19) United States
(12) Patent Application Publication
(10) Pub. No.: US 2012/0007434 A1
(43) Pub. Date: Jan. 12, 2012

(54) THREE-DIMENSIONAL PHOTOVOLTAIC APPARATUS AND METHOD

(75) Inventors: David John Perreault, Brookline, MA (US); Vladimir Bulovic, Lexington, MA (US); Jeffrey C. Grossman, Brookline, MA (US); Marco Bernardi, Cambridge, MA (US); Nicola Ferralis, Cambridge, MA (US)

(73) Assignee: MASSACHUSETTS INSTITUTE OF TECHNOLOGY, Cambridge Center, MA (US)

(21) Appl. No.: 13/021,373

(22) Filed: Feb. 4, 2011

Related U.S. Application Data
(60) Provisional application No. 61/301,467, filed on Feb. 4, 2010.

(51) Int. Cl. H02J 4/00; H01L 31/0236; G06F 17/50; H01L 31/052

(52) U.S. Cl. 307/82; 136/246; 136/256; 716/123

(57) ABSTRACT

Three-dimensional photovoltaic devices and power conversion structures associated therewith are provided.

This application claims the benefit of U.S. Provisional Appln. No. 61/301,467 filed Feb. 4, 2010, which is incorporated herein by reference as if fully set forth.

This invention was made in part under Grant EEC-0634750 awarded by the National Science Foundation through the Network for Computational Nanotechnology. The government has certain rights in the invention.

### FIELD

The disclosure herein relates to photovoltaics.

### BACKGROUND

Efforts in materials selection and optimization of solar cell designs has led to three generations of photovoltaic (PV) architectures in which organic and inorganic materials are arranged to maximize exciton generation, charge separation, charge transport and collection based on the known physical processes taking place in the device. Nanostructuring of high-efficiency active layers or micron scale arrangement of stacked layers in a cell has been used in an effort to develop three dimensionality of photovoltaic design. The pursuit of cost reduction leaves little room for material waste. As a consequence, the planar arrangement of increasingly thin flat panels has been adopted to optimize the generated power-to-material ratio and avoid inter-cell shading. The flat panel shape also facilitates straightforward rooftop installation and is well suited to standard large-scale semiconductor fabrication techniques. The paradigm of the flat, quasi two-dimensional solar cell has rarely been challenged.

### SUMMARY

In an aspect, the invention relates to a three-dimensional photovoltaic device. The three-dimensional photovoltaic device includes one or more solar cells arranged within a volume. The one or more solar cells have a photovoltaic surface having at least one concave face and a first area and a second area. The first area is configured to reflect light to the second area.

In an aspect, the invention relates to a system including a plurality of three-dimensional photovoltaic devices. Each of the three-dimensional photovoltaic devices includes respectively one or more solar cells arranged within a volume. The respective one or more solar cells have a respective photovoltaic surface having at least one respective concave face and a respective first area and a respective second area. The respective first area is configured to reflect light to the respective second area.

In an aspect, the invention relates to a method of optimizing a three-dimensional photovoltaic device. The method includes defining a plurality of devices. Each of the devices includes a respective plurality of solar cells having coordinates in Cartesian space. Each of the respective solar cells has a respective geometric shape and the respective plurality of solar cells for each of the plurality of devices are confined to a respective volume. The respective volume includes a first face, a second face, a third face, and a fourth face. The method also includes testing the energy produced by each of the plurality of devices. The method also includes randomly selecting a set of s devices from the plurality of devices and choosing one of the devices in the set of s to proceed to a mating pool. The one of the devices is chosen based on the energy of the one being higher than the energy of the devices remaining in the set of s. The method also includes reiterating the randomly selecting step until two or more of the devices are in the mating pool; forming random pairs of the devices in the mating pool, crossing solar cell coordinates within the random pairs, and perturbing at least one coordinate of the solar cells in the random pairs. The method also includes assessing the energy production of the devices; and repeating the testing, selecting, reiterating, forming, crossing, perturbing and assessing steps until a three-dimensional structure with maximal energy production is achieved.

### BRIEF DESCRIPTION OF THE DRAWINGS

The following detailed description of the preferred embodiments will be better understood when read in conjunction with the appended drawings. For the purpose of illustrating the invention, there are shown in the drawings embodiments which are presently preferred. It is understood, however, that the invention is not limited to the precise arrangements and instrumentalities shown. In the drawings:

FIG. 1 illustrates a schematic of a 3-dimensional photovoltaic device (3DPV) structure referred to in example 1 as a “funnel,” which is a simplified version of a genetic algorithm (GA)-optimized structure, but retains superior performance, like that of the GA-optimized structure, over other shapes.

FIG. 2 illustrates a schematic of a 3DPV structure referred to in example 1 as a GA optimized structure with 64 triangles inside the bounding box.

FIGS. 3.1A-B, 3.2 A-B, 3.3 A-B, 3.4 A-B, 3.5 A-B and 3.6 A-B, illustrate embodiments of three-dimensional photovoltaic devices having different architectures with respect to each other.

FIG. 4 illustrates an embodiment of a foldable three-dimensional photovoltaic.

FIG. 5 illustrates photovoltaic technologies that can be used in embodiments of a three-dimensional photovoltaic. FIG. 5 is re-produced from the National Renewable Energy Laboratory.

FIG. 6 illustrates a plot of the energy produced in a day by GA optimized 3DPV structures compared to that of a flat panel in the same conditions. The inset shows the power generated during the day for the flat panel compared to the 3DPV at height=10 m.

FIG. 7 illustrates energy produced in a day by PV structures made with materials of different reflectance, here defined as the ratio of the reflected power with the total incident power under solar illumination. The single-reflection approximation used here underestimates the energy produced at higher reflectance, so that the GA curve would have a smaller slope if the simulation accounted for infinite reflections.

FIG. 8 illustrates structures optimized with different levels of reflectance.

### DETAILED DESCRIPTION OF EMBODIMENTS

Certain terminology is used in the following description for convenience only and is not limiting. The words “right,” “left,” “top,” and “bottom” designate directions in the drawings to which reference is made. The words “a,” and “one,” as used in the claims and in the corresponding portions of the specification, are defined as including one or more of the referenced item unless specifically stated otherwise. The phrase “at least one” followed by a list of two or more items, such as “A, B, or C,” means any individual one of A, B or C as well as any combination thereof.

Photovoltaics, two-dimensional photovoltaic structures, photovoltaic materials, and electrical connections involving photovoltaics known in the art may be provided in embodiments herein.

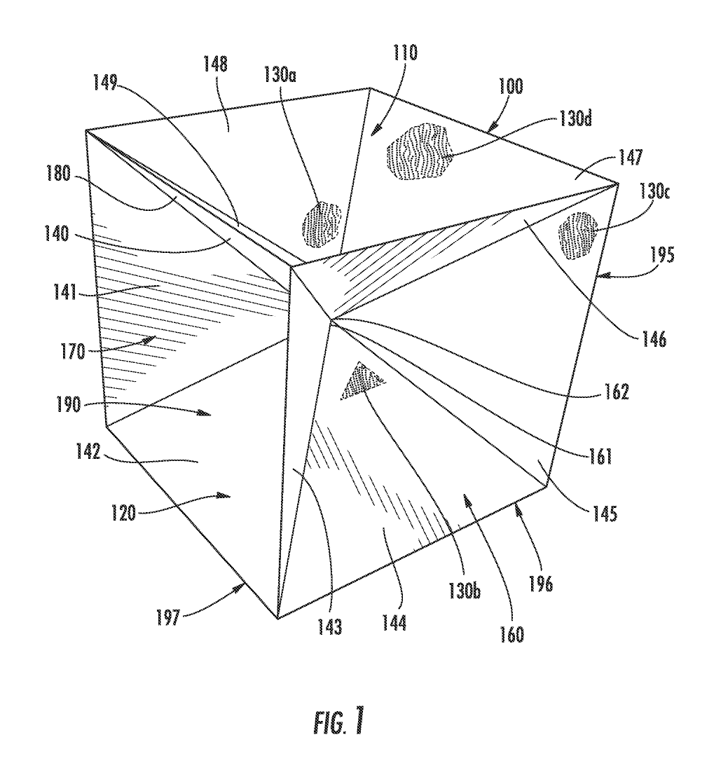

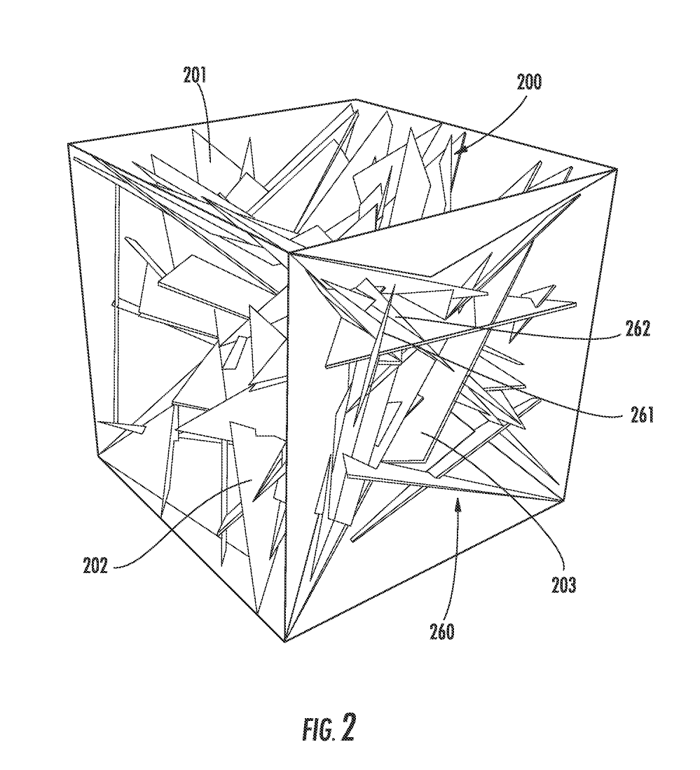

Referring to FIG. 1, a three-dimensional photovoltaic device 100 of an embodiment may include one or more solar-power collecting structures arranged within a volume 110, wherein the solar-power collecting structures include one or more solar cells and form a photovoltaic surface 120. A three-dimensional photovoltaic device can be divided into one or more zones, and FIG. 1 illustrates zones 130a, 130b, 130c, and 130d.

FIG. 1 illustrates portions of the photovoltaic surface that are part of zones 130b, 130c, and 130d, and these portions are within one respective two-dimensional surface of one face of the three-dimensional photovoltaic device. A zone is not, however, restricted to a two-dimensional contiguous area on a single face of a three-dimensional photovoltaic. Instead a zone can include areas that are discontinuous with one another. Further, a single area within a zone may extend to one or more faces or sub-faces of a three-dimensional photovoltaic. In addition, different points within a zone may have different depths within the space defined by the three-dimensional photovoltaic.

Still referring to FIG. 1, the zone 130a has relatively the same shading across the area of the zone. In addition, FIG. 1 illustrates the same relative shading level across the respective areas of the zones 130b, 130c, and 130d. The relatively similar shading across the respective areas of 130a, 130b, 130c, and 130d indicates that each individual zone has a common characteristic across the surface of the respective zone. As illustrated in FIG. 1, regions of the three-dimensional photovoltaic device may be used to define a zone by common characteristics across the region. A zone may also be defined by a combination of characteristics. Two non-limiting examples of characteristics used to define a zone alone or in combination include performance and physical characteristics. In an embodiment, a zone is an area of a three-dimensional photovoltaic device that receives relatively constant insolation across the zone during a given period of exposure. In an embodiment, a zone is an area of a three-dimensional photovoltaic device that receives the same insolation across the zone during a given period of exposure. In an embodiment, a zone is an area of a three-dimensional photovoltaic device where each point within the area receives insolation within 10% to 25% of the mean value of insolation across the area during a given period of exposure. In an embodiment, a zone is an area of a three-dimensional photovoltaic device where each point within the area receives insolation within 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191, 192, 193, 194, 195, 196, 197, 198, 199, 200, 201, 202, 203, 204, 205, 206, 207, 208, 209, 210, 211, 212, 213, 214, 215, 216, 217, 218, 219, 220, 221, 222, 223, 224, 225, 226, 227, 228, 229, 230, 231, 232, 233, 234, 235, 236, 237, 238, 239, 240, 241, 242, 243, 244, 245, 246, 247, 248, 249, 250, 251, 252, 253, 254, 255, 256, 257, 258, 259, 260, 261, 262, 263, 264, 265, 266, 267, 268, 269, 270, 271, 272, 273, 274, 275, 276, 277, 278, 279, 280, 281, 282, 283, 284, 285, 286, 287, 288, 289, 290, 291, 292, 293, 294, 295, 296, 297, 298, 299, or 300% of the mean value of insolation across the area during a given period of exposure. In an embodiment, a zone is an area of a three-dimensional photovoltaic device where each point within the area receives insolation within a range between and including any two integer values selected from 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191, 192, 193, 194, 195, 196, 197, 198, 199, 200, 201, 202, 203, 204, 205, 206, 207, 208, 209, 210, 211, 212, 213, 214, 215, 216, 217, 218, 219, 220, 221, 222, 223, 224, 225, 226, 227, 228, 229, 230, 231, 232, 233, 234, 235, 236, 237, 238, 239, 240, 241, 242, 243, 244, 245, 246, 247, 248, 249, 250, 251, 252, 253, 254, 255, 256, 257, 258, 259, 260, 261, 262, 263, 264, 265, 266, 267, 268, 269, 270, 271, 272, 273, 274, 275, 276, 277, 278, 279, 280, 281, 282, 283, 284, 285, 286, 287, 288, 289, 290, 291, 292, 293, 294, 295, 296, 297, 298, 299, or 300% of the mean value of insolation across the area during a given period of exposure. The given period of exposure may be any period. The given period may be a less than a day, a day, a week, a month, or a year. In an embodiment, amount or percent of insolation is measured for exposure under normal operation. In an embodiment, one or more small portion or point in a zone may receive no light: that is off by 100% of the average across the zone. In an embodiment, an area or point is excluded from a zone if it receives five times the average insolation across the area under consideration in a given period of time. In an embodiment, an area or point is excluded from a zone if it receives more than three times, more than four times or more than five times the average insolation across an area under consideration when the zone is defined as an area of a three-dimensional photovoltaic device where each point within the area receives insolation within 300% of the mean value of insolation across the area during a given period of exposure. The mean value of insolation may be expressed as a spatial average—a measure of variation across the zone at a given time.

In an embodiment, a zone is an area of a three-dimensional photovoltaic device that is designed to receive relatively constant insolation across the zone during a given period of exposure. In an embodiment, a zone is an area of a three-dimensional photovoltaic device that is designed to receive the same insolation across the zone during a given period of exposure. In an embodiment, a zone is an area of a three-dimensional photovoltaic device where each point within the area is designed to receive insolation within 10% to 25% of the mean value of insolation across the area during a given period of exposure. In an embodiment, a zone is an area of a three-dimensional photovoltaic device where each point within the area is designed to receive insolation within 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191, 192, 193, 194, 195, 196, 197, 198, 199, 200, 201, 202, 203, 204, 205, 206, 207, 208, 209, 210, 211, 212, 213, 214, 215, 216, 217, 218, 219, 220, 221, 222, 223, 224, 225, 226, 227, 228, 229, 230, 231, 232, 233, 234, 235, 236, 237, 238, 239, 240, 241, 242, 243, 244, 245, 246, 247, 248, 249, 250, 251, 252, 253, 254, 255, 256, 257, 258, 259, 260, 261, 262, 263, 264, 265, 266, 267, 268, 269, 270, 271, 272, 273, 274, 275, 276, 277, 278, 279, 280, 281, 282, 283, 284, 285, 286, 287, 288, 289, 290, 291, 292, 293, 294, 295, 296, 297, 298, 299, or 300% of the mean value of insolation across the area during a given period of exposure. In an embodiment, a zone is an area of a three-dimensional photovoltaic device where each point within the area is designed to receive insolation within a range between and including any two integer values selected from 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 113, 114, 115, 116, 117, 118, 119, 120, 121, 122, 123, 124, 125, 126, 127, 128, 129, 130, 131, 132, 133, 134, 135, 136, 137, 138, 139, 140, 141, 142, 143, 144, 145, 146, 147, 148, 149, 150, 151, 152, 153, 154, 155, 156, 157, 158, 159, 160, 161, 162, 163, 164, 165, 166, 167, 168, 169, 170, 171, 172, 173, 174, 175, 176, 177, 178, 179, 180, 181, 182, 183, 184, 185, 186, 187, 188, 189, 190, 191, 192, 193, 194, 195, 196, 197, 198, 199, 200, 201, 202, 203, 204, 205, 206, 207, 208, 209, 210, 211, 212, 213, 214, 215, 216, 217, 218, 219, 220, 221, 222, 223, 224, 225, 226, 227, 228, 229, 230, 231, 232, 233, 234, 235, 236, 237, 238, 239, 240, 241, 242, 243, 244, 245, 246, 247, 248, 249, 250, 251, 252, 253, 254, 255, 256, 257, 258, 259, 260, 261, 262, 263, 264, 265, 266, 267, 268, 269, 270, 271, 272, 273, 274, 275, 276, 277, 278, 279, 280, 281, 282, 283, 284, 285, 286, 287, 288, 289, 290, 291, 292, 293, 294, 295, 296, 297, 298, 299, or 300% of the mean value of insolation across the area during a given period of exposure.

In an embodiment, a zone is an area of a three-dimensional photovoltaic device where each point within the area receives any of the above listed levels of insolation within each point in time during the specified time, or where the spatial variations are further averaged over the specified period of time or averaged with a moving window over the specified period of time.

A three-dimensional photovoltaic device may be optimized for different locations, seasons, or periods of insolation.

A three-dimensional photovoltaic device may include electrical connections to form operable connections between the components of the three-dimensional photovoltaic device or other structures. Any suitable electrical connection is contemplated and non-limiting examples may be found in references cited in example 3, below, that are incorporated herein by reference as if fully set forth. The components of a three-dimensional photovoltaic device may be connected to power conversion components and linked in a power conversion architecture to one another. Optionally, individual three-dimensional photovoltaic devices are also connected to power conversion components. In addition, individual three-dimensional photovoltaic devices may be connected to one another through a power conversion architecture.

As illustrated in FIG. 1, the three-dimensional photovoltaic device may include a particular shape, and the embodiment illustrated includes sub-faces 140-149. The individual sub-faces 140-149 may include one or more solar cell(s). In addition, a single solar cell may extend to more than one face of a three-dimensional photovoltaic. Embodiments not shown include three-dimensional photovoltaic devices with different shapes.

In an embodiment, a three-dimensional photovoltaic device includes one or more individual solar-power collecting structures, which may be solar cells. Solar cell material and ways of operably connecting solar cells known in the art may be provided in embodiments herein. The solar cells can be but are not limited to double-sided flat panel solar cells.

A three-dimensional photovoltaic device may have a shape selected from but not limited to a cube, a rectangular prism, a parallelepiped, a sphere, a cylinder and a pyramid. The walls of these structures may include a configuration selected from but not limited to flat, curved, indented, caved in or combinations thereof. As used herein, a “concave” face may refer to a face of a three-dimensional photovoltaic device where the faces curves inward or is caved in. As illustrated in FIG. 1, sub-faces 140, 141, 142 and 143 are caved in toward the midpoint and form concave face 170. In an embodiment, a three-dimensional photovoltaic device has at least one concave face. The degree of concavity of one face may vary from that of another face on one three-dimensional photovoltaic device. The degree of concavity of more than one concave face may be the same. The degree of concavity may be expressed as the distance that the center of the concave face is displaced from the outline of a starting volume toward the center of the three-dimensional photovoltaic device. The distance displaced may be expressed as a percent distance that the center of the concave face is displaced from the outline of a starting volume toward the center of the three-dimensional photovoltaic device. A measure of 0% may correspond to a face that has no displacement from the outline of the starting volume. A measure of 100% may correspond to a face that is displaced from the outline of the starting volume all the way to the midpoint of the starting volume. A starting volume could be conceptualized as any shape; for example, a cube, a rectangular prism, a parallelepiped, a sphere, a cylinder and a pyramid. The percent distance between the outline of the starting volume and the center of the three-dimensional photovoltaic device may be less than 1, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 or 100%, or a range between any two integers in the preceding list. As used herein, “displaced” or “displacement” is used to refer to the shape of a face of a three-dimensional photovoltaic device in reference to a starting volume, rather than to an act of forming a flat face or physically moving the face to a new position. Although, methods of making a three-dimensional photovoltaic device may or may not include such acts. A starting volume may be a cube. As illustrated in FIG. 1, the starting volume has a height 195, a width 196 and a depth 197.

As illustrated in FIG. 1, the center 161 is displaced from a conceptual cubic starting volume toward the midpoint 162 of the three-dimensional photovoltaic device 100. The three-dimensional photovoltaic device 100 illustrated is a box, and each exposed side is caved in at its center to extend toward the midpoint of the box.

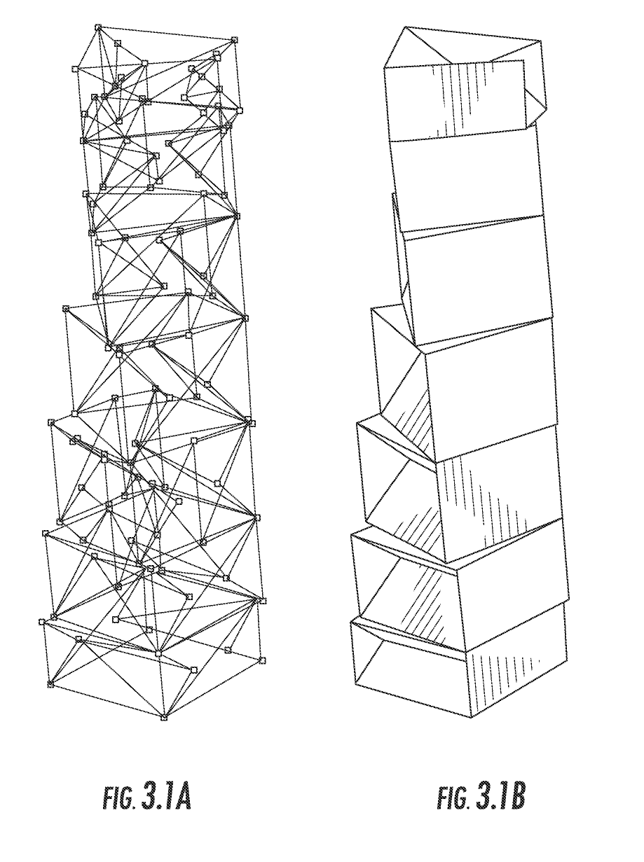

FIG. 2 illustrates a three-dimensional photovoltaic device 200 with an overall box shape. Individual solar cells within the three-dimensional photovoltaic device 200 are illustrated. As an example, three individual solar cells are indicated as the triangles 201, 202, and 203 in FIG. 2. The three-dimensional photovoltaic device 200 of FIG. 2 also has sides where the center is caved in to extend toward the midpoint of the box. For example, side 260 has its center 261 extending inward to the midpoint 262 of the three-dimensional photovoltaic device 200.

In an embodiment, at least a portion of the individual solar cells within a three-dimensional photovoltaic device have their edges aligned with the edges of the enclosed volume of the three-dimensional photovoltaic.

The three-dimensional photovoltaic device 100 and the three-dimensional photovoltaic device 200 have six sides each. One side may be a side installed on a surface or otherwise un-exposed to solar radiation. Three of the six sides in each three-dimensional photovoltaic device 100, 200 are illustrated as caved in and extending toward the midpoint. Fourth and fifth sides not shown in if FIG. 1 or 2 may be caved in and extend toward the midpoint. The sixth side configuration may include a similar configuration as one of the other five sides, or it may include but is not limited to solar collecting structures in a different configuration, or non-solar collecting structures. The sixth side may include one or more electrical device, one or more insulating device, one or more support device and/or one or more fastener to attach the three-dimensional photovoltaic device to another device. The other device may be any device, including a substrate. The other device may be but is not limited to another three-dimensional photovoltaic device. The substrate may be but is not limited to clothing, cloth, soil, concrete, wood or plastic. A three-dimensional photovoltaic device may include one or more fastener to attach the three-dimensional photovoltaic device to another device or substrate.

The embodiments illustrated in FIGS. 1 and 2 do not limit the number of non-concave faces or non-photovoltaic surfaces. Any one or more face of a three-dimensional photovoltaic may be non-concave. Any one or more face of a three-dimensional photovoltaic device may be configured to be partially or completely obscured from insolation, or may lack a photovoltaic surface. Portions of a three-dimensional photovoltaic device that are configured to be obscured from insolation or that lack a photovoltaic surface may be adapted to other functions and include features adapted to the other functions. For example, a group of two or more photovoltaic devices may have connection surfaces where the connecting surface from one photovoltaic device can be attached to the connecting surface of another photovoltaic device. The respective connecting surfaces may be configured to be obscured from insolation or may lack a photovoltaic surface. The attachment may include direct contact or be through an adapter. An adapter may be an insulating layer, a strut, or any other structure intermediate between one three dimensional photovoltaic device and another. The attachment may be accomplished through any suitable structures including being fixed through a weld, an adhesive, a fastener, a screw, a latch and hook, etc. The attachment may be accomplished by resting the connecting surface from one photovoltaic device against the connecting surface of another photovoltaic device (directly or through an adaptor). Groups of three-dimensional photovoltaic devices may be provided with connecting surfaces such that the individual three-dimensional photovoltaic devices in the group are modular. The overall shape of the group could be adapted by re-arranging the modular pieces to a desired configuration.

In an embodiment, the solar cells of a three-dimensional photovoltaic device have a spectral-averaged power reflectance level, R, and the value of R for each solar cell is approximately the same as the remaining solar cells in the three-dimensional photovoltaic. In an embodiment, the solar cells of a three-dimensional photovoltaic device have a spectral-averaged power reflectance level, R, and the value of R for each solar cell is the same. In an embodiment, the spectral-averaged power reflectance for each solar cell is 4.1%. In some embodiments, R is constant between solar cell surfaces, but may be any value selected in from the range of 4% to 50%. In some embodiments, R may be varied across the solar cell surfaces.

One area of a three-dimensional photovoltaic device may be configured to receive light reflected from another area of the device. For example, area 190 in FIG. 1 may receive light reflected from area 191 if the incident light has the correct angle of incidence. Light having the correct angle of incidence may be present for one or more of a variety of conditions including but not limited to the following. Light at the correct angle of incidence may be present at a time point for a given period for insolation. Light at the correct angle of incidence may be present or maintained due to movement of a three-dimensional photovoltaic device relative to the light source.

A three-dimensional photovoltaic device zone may include but is not limited to a group of structures having a single solar cell, a group of solar cells connected in series, and a group of solar cells connected in parallel.

In an embodiment, the power conversion architecture of a three-dimensional photovoltaic device includes a plurality of dc-dc power converters having converter inputs and converter outputs, and each zone is connected to a respective converter input and each converter output is connected to a common bus. Each dc-dc power converter could be but is not limited to one selected from a buck converter, a boost converter, a flyback converter, a Cuk converter, a SEPIC converter and a Zeta converter. The respective converters may provide maximum power point tracking. A system may be provided that includes a plurality of the three-dimensional photovoltaic device having the conversion architecture set forth in this paragraph, and where the respective common bus of individual ones of the plurality of the three-dimensional photovoltaic device are operably connected to one another. The individual three-dimensional photovoltaic device of this system may be operably connected to one another through connections to an inverter, which may be a module-integrated inverter.

In an embodiment, a three-dimensional photovoltaic device includes power conversion architecture having a plurality of dc-dc power converters having respective converter inputs and converter outputs, and each zone is connected to a respective input. Further, the converter outputs are connected to one another in series or cascade, and the output of the three-dimensional photovoltaic device is connected to a dc-ac inverter. Individual zones may be bypassed when the particular zone has low power output. Bypass may be achieved by selectively switching out a low power output zone and bypassing it electrically. Bypass may be affected when the net power realized by bypassing is higher than if the zone is left in operation. A system may be provided that includes a plurality of the three-dimensional photovoltaic devices having the power conversion architecture set forth in this paragraph, and where the respective dc-ac inverters of individual ones of the plurality of the three-dimensional photovoltaic devices are operably connected to one another. The individual three-dimensional photovoltaic devices of this system may be operably connected to one another through connections to an inverter, which may be a module-integrated inverter.

In an embodiment, the power conversion architecture of a three-dimensional photovoltaic device includes a plurality of dc-dc power converters having converter inputs and converter outputs. Each zone is connected to a respective converter input and the converter outputs are connected in series. A system may be provided that includes a plurality of the three-dimensional photovoltaic devices having the power conversion architecture set forth in this paragraph, wherein individual ones of the plurality of the three-dimensional photovoltaic devices are operably connected to one another. The plurality of the three-dimensional photovoltaic devices may be operably connected to one another through respective connections to an inverter. Each zone in a three-dimensional photovoltaic device or system may be connected to an inverter or microinverter. The three-dimensional photovoltaic devices may be operably connected to one another, and the operable connection may include connections to an inverter, which may be a module-integrated inverter.

Embodiments herein include a system including a plurality of three-dimensional photovoltaic devices, wherein an individual three-dimensional photovoltaic device includes any suitable power conversion architecture, including any one of the power conversion architectures described above. The different three-dimensional photovoltaic devices of this system may, thus, include the same or different power conversion architectures with respect to one another. Embodiments herein also include any operable connection between elements of a three-dimensional photovoltaic, between individual three-dimensional photovoltaic, or with the remaining elements of a solar energy collecting device. See, for non-limiting examples the references in example 3 that are incorporated by reference herein as if fully set forth.

Embodiments herein include methods of optimizing a three-dimensional photovoltaic device. The methods may include defining devices as a plurality of solar cells having configurations of geometric shapes in Cartesian space and confined to a volume. Each solar cell within each device may be assigned a set of coordinates. The volume can be any geometric volume, including but not limited to any of those set forth above. In an embodiment, the volume includes a first face pointing east, a second face pointing west, a third face pointing north, and a fourth face pointing south. The methods may include testing the energy produced by each of the plurality of devices. The methods may also include randomly selecting a set of s devices from the plurality of devices and choosing one of the devices in the set of s devices to proceed to a mating pool. The individual device may be chosen based on the energy of the one being higher than the energy of the remaining devices in the set of s. The selecting step may be reiterated two or more times until two or more of the devices are in the mating pool. Random pairs of the devices may be formed from those in the mating pool, and solar cell coordinates may be crossed within the random pairs. By crossing the solar cell coordinates, the solar cell of one of the devices is replaced by a solar cell of the other, and vice versa. The methods may also include perturbing each coordinate of the solar cells in the random pairs. The range of perturbation could be 1-10%. The energy production of the devices after crossing and perturbation may be assessed. Further, the testing, selecting, reiterating, forming, and assessing steps may be repeated until a three-dimensional structure with maximal energy production is achieved. The three-dimensional structure with maximal energy production may be provided as the structure of the optimized three-dimensional photovoltaic device. In an embodiment, maximal energy refers to the highest value for the energy that the algorithm is able to find in a given simulation. In an embodiment, the shape achieved at maximal energy for a given set of parameters is the shape of the optimized three-dimensional photovoltaic device.

In embodiments, a method of optimizing a three-dimensional photovoltaic device may include but is not limited to one or more of the following features:
Solar cells shaped as triangles;
64-1,000 solar cells;
Double-sided solar cells;
A volume having constant dimensions;
A volume shaped as a cube with an area footprint of 10×10 m² and a fixed height selected from the range of 2 to 10 m;
A volume shaped as a cube with an area footprint of 10×10 m² and a variable height selected from the range of 2 to 10 m;
A volume having variable dimensions;
Solar cells having a spectral-averaged power reflectance, R, and R is constant;
Solar cells having a spectral-averaged power reflectance, R, and R=4.1%;
Solar cells having a spectral-averaged power reflectance, R, and R is variable;
Solar cells having a power conversion efficiency, h, and h is constant;
Solar cells having a power conversion efficiency, h, and h=6%; and
Solar cells having a power conversion efficiency, h, and h is variable.

In an embodiment, a method of optimizing a three-dimensional photovoltaic device may include but is not limited testing or testing or selecting steps for a selected time and/or a selected place. The selected time may be but is not limited to a portion of a day, a day, more than one day, a week, a month, a season or a year. The selected place may be but is not limited to a position relative to local structures (for example but not limited to buildings, cliffs, towers, and forests) or geographic position (for example but not limited to the Equator, the Tropic of Cancer, the Tropic of Capricorn, the South Pole, the North Pole or any point in between).

The embodiments herein include optimizing a photovoltaic and can also be used to provide resistance to wind, dust and other environmental influences. These features can be achieved at least in part through the three-dimensional structure of a three-dimensional photovoltaic. For example, a structure within the three-dimensional photovoltaic device may provide shelter to other portions of the device. The shelter may provide increased resistance to wind, dust and/or other environmental influences.

Embodiments include a folded three-dimensional photovoltaic. Embodiments also include deploying a three-dimensional photovoltaic device or a system including one or more three-dimensional photovoltaic device by unfolding a folded three-dimensional photovoltaic device in situ. Embodiments also include folding a three-dimensional photovoltaic device in situ. A folded three-dimensional photovoltaic device may be provided for one or more of the following reasons: to save space on site, to save space during transport, to protect the three-dimensional photovoltaic device from damage. The damage protection may include but is not limited to protecting the three-dimensional photovoltaic device from physical abrasion, wind, dust and other environmental influences.

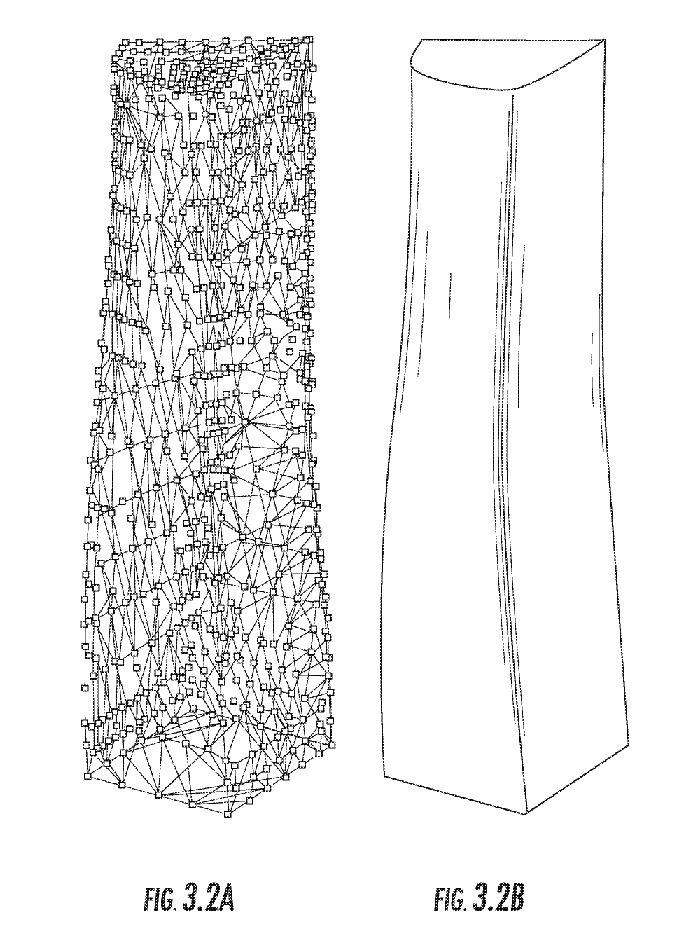

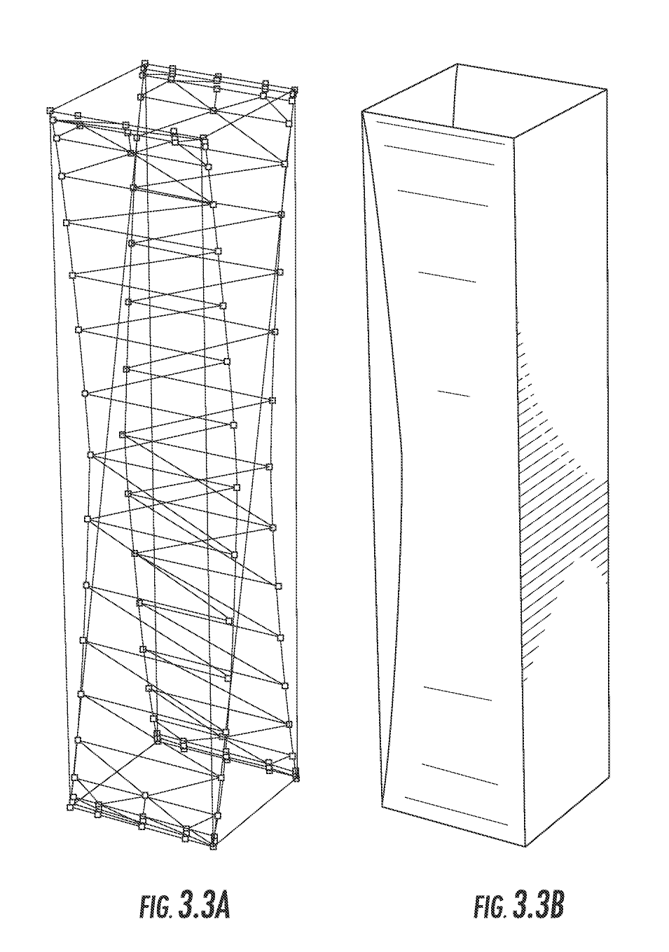

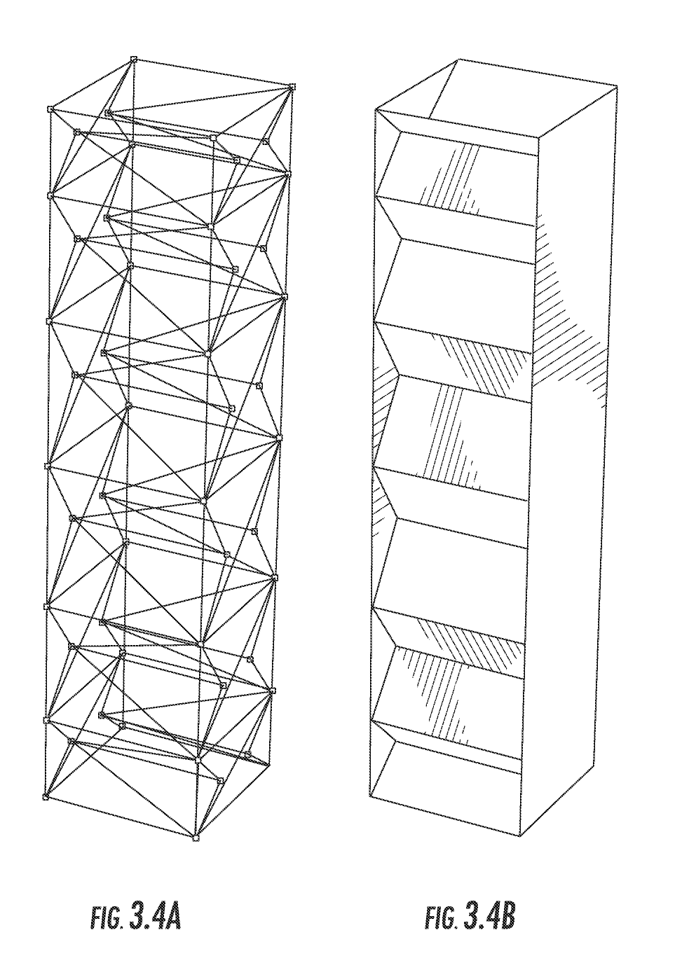

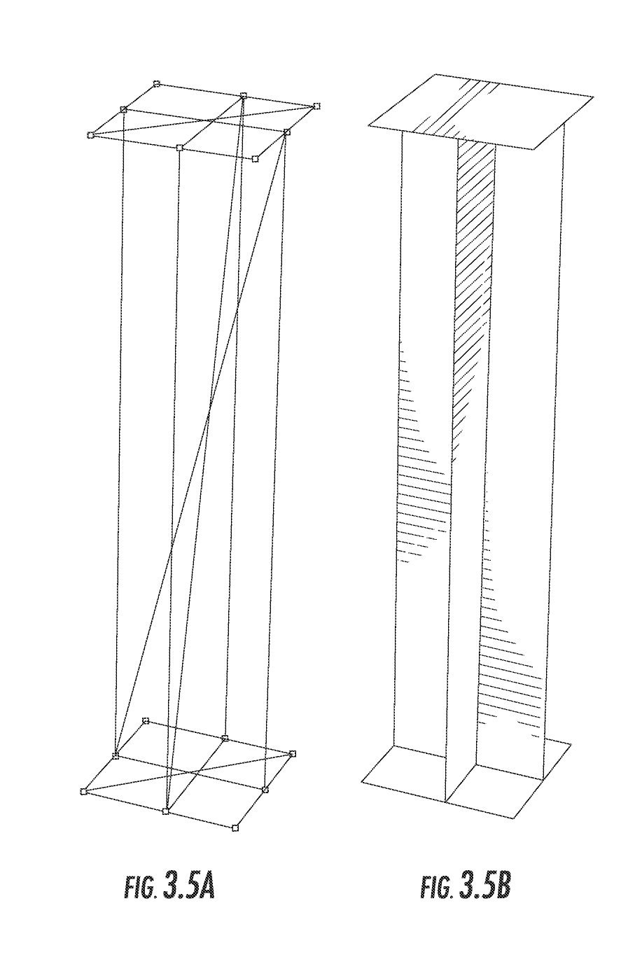

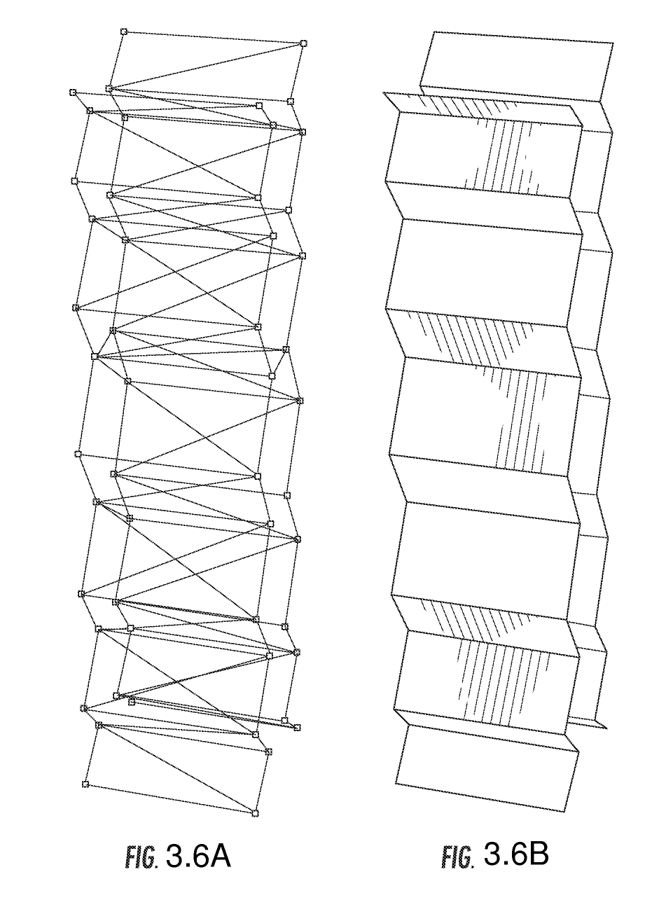

FIGS. 3.1A-B, 3.2 A-B, 3.3 A-B, 3.4 A-B, 3.5 A-B and 3.6 A-B illustrate embodiments for a three-dimensional photovoltaic device architecture. As shown, the architecture for a three-dimensional photovoltaic may include a variety of shapes. The shape of one unit of a three-dimensional photovoltaic may be repeated in another unit identically, or with modification or rotation.

A three-dimensional photovoltaic device cell can enable simplified photovoltaic installation where the three-dimensional shape of the photovoltaic. In an embodiment, a three-dimensional photovoltaic device provides a rigid mechanical structure that can be deployed with minimal need for additional mechanical supports. Referring to FIG. 4, a non-limiting embodiment of a simple three-dimensional photovoltaic device with six photovoltaic parts (PVs) that can be unfolded to form a standing photovoltaic structure is provided. Any hinging mechanism may be provided between the photovoltaic parts. Hinging may enable ease of storage of the three-dimensional photovoltaic device prior to deployment. Hinging may also provide a way to preserve, ensure, or test that electrical interconnects between the photovoltaic parts are wired prior to deployment.

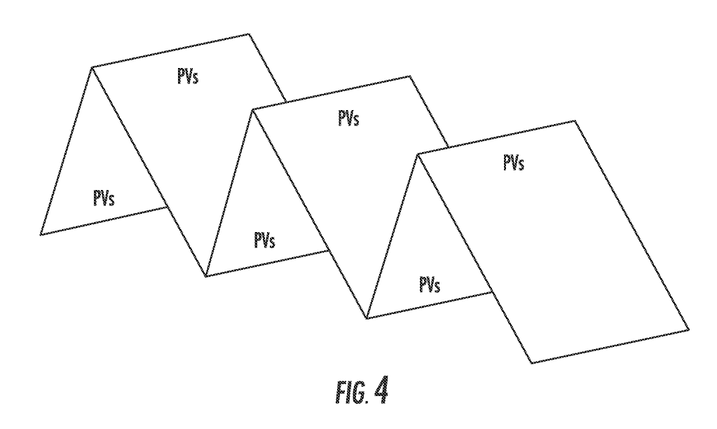

Referring to FIG. 5, any non-tracking PV technology plotted in the chart below could be used in a three-dimensional photovoltaic device cell configuration. Indeed, all known solar cell technologies may be compatible with deployment in three-dimensional photovoltaic device cell structures. For example, embodiments herein may include but are not limited to one or more material selected from amorphous, microcrystalline, polycrystalline, and single crystal photovoltaics. The photovoltaic devices may be fabricated out of group IV, groups III-V, or group II-VI materials, or combinations of thin films of these materials. Embodiments herein may also include nano-structured photovoltaics made of molecules, polymers, dendrimers, quantum dots, quantum rods, quantum wires, tetra-pods, nanotubes, or nanowires. Non-tracking concentrator geometries could also be used.

Unexpected gains in output have been observed based on the latitude where a three-dimensional photovoltaic device or system may be implemented. In comparison to a two-dimensional device having the same area foot print, a three-dimensional photovoltaic device provides 2-2.2 fold gains at the equator and approximately 3.8 fold gains at the poles.

Unexpected gains have also been observed based on the extent of time a three-dimensional photovoltaic device or system may be implemented. Flat panels that lack tracking typically show a difference in power generated between summer and winter of two fold. However, a three-dimensional photovoltaic device having the same area footprint shows only a 30-40% decrease in power generated in winter with respect to power generated in summer. This result was obtained even when a three-dimensional photovoltaic device was stationary (i.e., not tracked).

A three-dimensional photovoltaic device or system thereof may be incorporated in a larger system including devices that implement the three-dimensional photovoltaic device or system thereof. An example of a larger system includes one or more charging stations used to charge one or more electric devices. Each charging stations may be provided with one or more three-dimensional photovoltaic device or system thereof. A charging station may be separated from another charging station, if provided, by any desired distance. The desired distance may be selected based on at least one of arbitrary choice, the functionality of the one or more electric devices and the function of the larger system.

A larger system could be an assembly of charging stations for charging electric vehicles. The electric vehicles may be electric bicycles. Each charging station may form a node. The distance of one node to the next may be selected based at least one of an arbitrary choice, the range of the electric device, the average distance traveled by a user implementing the electric vehicle. The number of three-dimensional photovoltaic devices in a charging station may be provided based on the number of users expected for the charging station. The nodes may be provided such that the distance between one and the next is less than the range of a fully charged electric vehicle.

### List of Embodiments

The following list summarizes embodiments herein. The list does not exclude embodiments described elsewhere herein but not specifically enumerated in the list.

1. A three-dimensional photovoltaic device comprising: one or more solar cells arranged within a volume, the one or more solar cells having a photovoltaic surface having at least one concave face and a first area and a second area, wherein the first area is configured to reflect light to the second area.

2. The device of embodiment 1, wherein the photoelectric surface is continuous over one or more of the at least one concave face.

3. The device of any one of the previous embodiments, wherein the device photoelectric surface is continuous over each of the at least one concave face.

4. The device of any one of the previous embodiments, wherein the one or more solar cells include at least one flat panel solar cell.

5. The device of any one of the previous embodiments, wherein the one or more solar cells include at least one double-sided flat panel solar cell.

6. The device of any one of the previous embodiments, wherein the solar cells have a respective reflectance and the reflectance of each solar cell is same.

7. The device of any one of the previous embodiments, wherein the three-dimensional photovoltaic device has an outline with six faces and the at least one concave faces is at least four concave faces having respective centers positioned between 0 and 100% of the distance between the exterior of the outline and the midpoint.

8. The device of embodiment 7, wherein the percent of the distance is selected from the group consisting of 5, 10, 15, 20, 25, 30, 35, 40, 45, 50, 55, 60, 65, 70, 80, 85, 90, 91, 92, 93, 94, 95, 96, 97, 98, 99 and 100%.

9. The device of any one of embodiment 7 or 8, wherein the at least four concave faces are at least five concave faces.

10. The device of any one of the previous embodiments, wherein the volume has a height, a width and a depth defining twelve cube edges and the one or more solar cells have respective solar cell edges, and each of the cube edges includes a respective solar cell edge.

11. The device of embodiment 10, wherein each cube edge is a respective solar cell edge.

12. The device of any of the preceding embodiments further comprising one or more operably connected zones, wherein each of the one or more operably connected zones includes at least a portion of the photovoltaic surface; and a power conversion architecture operably connecting the one or more zones to at least one power output, wherein the one or more operably connected zones include areas of the three-dimensional photovoltaic that receive the same insolation level over a given period of insolation.

13. The device of embodiment 12, wherein the given period of insolation is selected from a period of one day, one day, a group of days, one week, one month, one season or one year.

14. The device of any one of the previous embodiments, wherein the volume has a height from 1 mm to 10 m, a width from 1 mm to 10 m, and a depth from 1 mm to 10 m.

15. The device of any one or more of the previous embodiments, wherein the volume has a midpoint, a height, a width and a depth, and the height is equal to the width and the depth.

16. The device of any one of the previous embodiments further comprising one or more operably connected zones, wherein each of the one or more operably connected zones includes at least a portion of the photovoltaic surface; and a power conversion architecture operably connecting the one or more zones to at least one power output, wherein respective ones of the one or more zones include at least one of a single one of the one or more solar cells, a group of the one or more solar cells connected in series, or a group of the one or more solar cells connected in parallel.

17. The device of any one embodiments 12-16, wherein the power conversion architecture includes a plurality of dc-dc power converters having converter inputs and converter outputs, and each of the one or more zones is connected to a respective converter input and each converter output is connected to a common bus.

18. The device of any one embodiments 12-17, wherein the power conversion architecture includes a plurality of dc-dc power converters having respective converter inputs and converter outputs, and each zone is connected to a respective input; the converter outputs are connected to one another in series or cascade; and the output of the three-dimensional photovoltaic device is connected to a dc-ac inverter.

19. The device of any one embodiments 12-18, wherein the power conversion architecture includes a plurality of dc-dc power converters having converter inputs and converter outputs, and each zone is connected to a respective converter input and the converter outputs are connected in series.

20. The device of any one of embodiments 17-19, wherein each dc-dc power converter is one selected from the group consisting of a buck converter, a boost converter, a flyback converter, a Cuk converter, a SEPIC converter, and a Zeta converter.

21. The device of any one of embodiments 17-20, wherein one or more of the respective converters provide maximum power point tracking.

22. The device of any one of embodiments 17-21, wherein an individual one of the zones may be bypassed when the respective zone has a low power output.

23. A system including a plurality of the devices of any of the previous embodiments operably connected through the at least one power output.

24. The system of embodiment 23, wherein the respective common bus of individual ones of the plurality of the three-dimensional photovoltaic devices are operably connected to one another through respective connections to a module-integrated inverter.

25. The system of any one of embodiments 23-24, wherein the power conversion architecture includes a plurality of dc-dc power converters having converter inputs and converter outputs, and each of the one or more zones is connected to a respective converter input and each converter output is connected to a common bus.

26. The system of any one of embodiments 23-24, wherein the power conversion architecture includes a plurality of dc-dc power converters having respective converter inputs and converter outputs, and each zone is connected to a respective input; the converter outputs are connected to one another in series or cascade; and the output of the three-dimensional photovoltaic device is connected to a dc-ac inverter.

27. The system embodiment 23, wherein the at least one power output is a dc-ac inverter and individual ones of the plurality of the three-dimensional photovoltaic devices are connected to one another through respective connections to the dc-ac inverter.

28. The system of any one of embodiments 23-27 further comprising a substrate fixed to one or more of the plurality of three-dimensional photovoltaic devices.

29. The system of embodiment 28, wherein the substrate is selected from the group consisting of clothing, paper, rock, brick, pavement, cement and soil.

30. The system of any one of embodiments 28-29, wherein the substrate is clothing.

31. The system of any one of embodiments 28-30, wherein the volume has a height above the substrate.

32. The system of any one of embodiments 29-31, wherein the volume has a height from 1 mm to 1 cm, a width from 1 mm to 1 cm, and a depth from 1 mm to 1 cm.

33. The system of any one of embodiments 23-32, wherein at least one of the plurality of the three-dimensional photovoltaic devices is fixed to a second of the plurality of the three-dimensional photovoltaic devices.

34. The device of any one of embodiments 1-22 further comprising a substrate fixed to three-dimensional photovoltaic device.

35. The device of embodiment 34, wherein the substrate is selected from the group consisting of clothing, paper, rock, brick, pavement, cement and soil.

36. The device of any one of embodiments 34-35, wherein the substrate is clothing.

37. The device of any one of embodiments 34-36, wherein the volume has a height above the substrate.

38. The device of any one of embodiments 34-37, wherein the volume has a height from 1 mm to 1 cm, a width from 1 mm to 1 cm, and a depth from 1 mm to 1 cm.

39. The device or system of any of the preceding embodiments, wherein the one or more solar cells have a power conversion efficiency, h, and h is constant between each of the solar cells in the device or in one device of the system.

40. The device or system of embodiment 39, wherein h is constant between each of the solar cells in each device of the system.

41. The device or system of one of embodiments 39 or 40, wherein h is 6%.

42. A method of optimizing or making a three-dimensional photovoltaic device comprising:

defining a plurality of devices, each of the devices including a respective plurality of solar cells having coordinates in Cartesian space, wherein each of the respective solar cells has a respective geometric shape and the respective plurality of solar cells for each of the plurality of devices are confined to a respective volume, and the respective volume includes a first face, a second face, a third face, and a fourth face; testing the energy produced by each of the plurality of devices; randomly selecting a set of s devices from the plurality of devices and choosing one of the devices in the set of s to proceed to a mating pool, wherein the one of the devices is chosen based on the energy of the one being higher than the energy of the devices remaining in the set of s; reiterating the randomly selecting step until two or more of the devices are in the mating pool; forming random pairs of the devices in the mating pool, crossing solar cell coordinates within the random pairs, and perturbing at least one coordinate of the solar cells in the random pairs; assessing the energy production of the devices; and repeating the testing, selecting, reiterating, forming, crossing, perturbing and assessing steps until a three-dimensional structure with maximal energy production is achieved.

43. The method of embodiment 42, wherein the geometric shapes are triangles.

44. The method of any one of embodiments 42-43, wherein the number of solar cells in the respective plurality of solar cells in each respective one of the devices is in the range of 64-1,000.

45. The method of any one of embodiments 42-44, wherein the solar cells are double-sided.

46. The method of any one of embodiments 42-45, wherein the volume has a height, a width and a depth.

47. The method of any of embodiments 42-46, wherein the volume has a an area footprint in a range from 1×1 cm² to 10×10 m² and a fixed height in a range from 1 mm to 10 m.

48. The method of embodiments 47, wherein the area footprint is 10×10 m² and the height is selected from the range of 2 to 10 m.

49. The method of any one of embodiments 42-48, wherein the solar cells have a spectral-averaged power reflectance, R, and R is constant.

50. The method embodiment 49, wherein R is 4.1%.

51. The method of any one of embodiments 42-50, wherein the solar cells have a power conversion efficiency, h, and h is constant.

52. The method of embodiment 51, wherein h is 6%.

53. The method of any one of embodiments 42-52, wherein the first face points east, the second face points west, the third face points north, and the fourth face points south.

54. The method of any of embodiments 42-43, wherein one or more of the testing and assessing steps are measured for insolation over a period of time independently selected for the testing and assessing steps.

55. The method of embodiment 54, wherein the period of time is selected from a portion of a day, a day, a group of days, a week, a month, a season or a year.

56. A device or system including the three-dimensional photovoltaic device optimized or made by the method of any of embodiments 42-55.

57. A three-dimensional photovoltaic device including a plurality of solar cells, wherein at least one of the solar cells is configured to accept light reflected by at least one of the other solar cells.

58. The device of embodiment 57, wherein at least one of the plurality of solar cells is a single sided solar cell.

59. The device of any one of embodiments 57-58, wherein at least one of the plurality of solar cells is a double sided solar cell.

60. The device of any one of embodiments 57-59, wherein at least one of the plurality of solar cells has at least one concave face.

Any single embodiment herein may be supplemented with one or more element from any one or more other embodiment herein. An element from one embodiment herein may be replaced by one or more element from one or more other embodiment herein.

Examples—The following non-limiting examples are provided to illustrate particular embodiments. The embodiments throughout may be supplemented with one or more detail from any one or more example below. An element from one embodiment herein may be replaced by one or more element from one or more example below.

### EXAMPLES

The following examples are provided for illustration of particular embodiments herein and are not limiting to any embodiment herein.

Myers, B, et al., Three-Dimensional Photovoltaics (2010), Applied Physics Letters 96, 071902 is incorporated herein by reference as if fully set forth.

### Example 1

### Three-Dimensional Photovoltaic Device Shape and Optimization

A reasonable three-dimensional photovoltaic device (3DPV) shape could appear to be a box open at the top made of double-sided solar cells, as this arrangement (here referred to as “open-box”) intuitively allows for light trapping by multiple reflections. However, an optimized 3DPV may differ from an open-box. Light reflection, incident angle, position with respect to the sun, panel arrangement, and other factors define a complicated optimization problem. In this example, optimal 3DPV shapes are explored systematically using a combination of a genetic algorithm (GA) and a code developed to compute the energy generated in one day by an arbitrary shaped 3D solar cell. The genetic algorithm approach is described in D. E. Goldberg, Genetic Algorithms in Search, Optimization, and Machine Learning (Addison-Wesley Professional, 1989), which is incorporated herein by reference as if fully set forth. See also, S. Kumara, Single and Multiobjective Genetic Algorithm Toolbox in C++ (Illinois Genetic Algorithms Laboratory, Report No. 2007016, 2007), which is incorporated by reference herein as if fully set forth. The single-objective version in S. Kumara, et al. was used in the simulations of this example. Any genetic algorithm could, however, be utilized in embodiments herein with appropriate adaptation, as is known in the art.

The solar-power-collecting structures were defined as configurations of triangles in Cartesian space confined to a rectangular box volume whose face normals pointed North, South, East, and West. The triangles represented double-sided flat panel solar cells, and within the GA are allowed to evolve their coordinates independently to produce an optimized 3D structure. In the GA, candidate 3D structures were combined using operations based on three principles of natural selection, namely selection, recombination, and mutation. The selection determined which structures would propagate to the next step, where they were modified by the recombination and mutation operators. The “tournament without replacement” selection scheme (B. L. Miller, and D. E. Goldberg, Evolutionary Computation 4, 113 (1996), which is incorporated herein by reference as if fully set forth) was used, in which s structures from the current population were chosen randomly and the one with the highest value of a fitness function proceeded to the mating pool, until a desired pool size was reached. In the simulations of this example s=2, and the fitness function corresponded to the energy that the individual structure produced in one day. Maximization of this energy was the single objective of the GA. The recombination step randomly paired 3D structures in the mating pool and with some probability (here 80%) crossed their triangle coordinates, causing the swapping of whole triangles. A two-point crossover recombination method was employed, wherein two indices are selected at random in the list of coordinates composing the chromosomes, and then the entire string of coordinates in between was traded between the pair of solutions. Finally, the mutation operator slightly perturbed each coordinate, for the purpose of searching a larger phase space. These three operations were performed until convergence was reached, and a 3DPV structure with maximal energy production was achieved. A solar position algorithm returned the azimuth and zenith angles of the apparent sun position as seen from the simulation location at successive time steps from sunrise to sunset. This example used the sun trajectory on a summer day in San Francisco for these particular calculations. At each step, the simulation computed the total power incident on each triangle using ray-tracing to account for inter-cell shadowing and for the angle of incidence of the incoming light. The sun was assumed to be a source of parallel rays, and cloud cover and all light-obstructions (except from other triangles in the structure) were neglected. For simplicity, it was assumed that all transmitted radiation counts toward the generated power, and only one reflection step (from solar cell surfaces) was taken into account. The triangles surfaces were assumed flat in the sense that all reflections were taken to be specular (θrefl=θincid). The opposite extreme, not implemented in this example but possible for the embodiments herein, would be Lambertian reflection, in which incident radiation scatters isotropically in the hemisphere. The number of ray-traces per cell (i.e., per triangle) was fixed to 100 during most simulations to limit computation time. After optimization, the final reported power values of the structures were evaluated with a larger standard number of ray-traces per cell (10,000), allowing convergence of the calculated energy value to better than 0.01%. The number of triangles, the dimensions of the box, the spectral-averaged power reflectance R and the power conversion efficiency h of the panels were kept fixed during a single simulation. A total of 64 triangles were used in all cases, with reflectance R=4.1% and efficiency h=6%. The reflectance value is typical for plastics, assuming an average refraction index of 1.505. The efficiency was set to 6% to simulate the best performance of state-of-the-art polymer solar cells. Tests with a larger number of triangles (up to 1000) in the bounding volume did not show significant variation in the optimal 3D shape or energy produced. Energy values for 3D structures are lower bounds since this example only implemented a single reflection per ray (to limit computation time) and did not account for ground reflections.

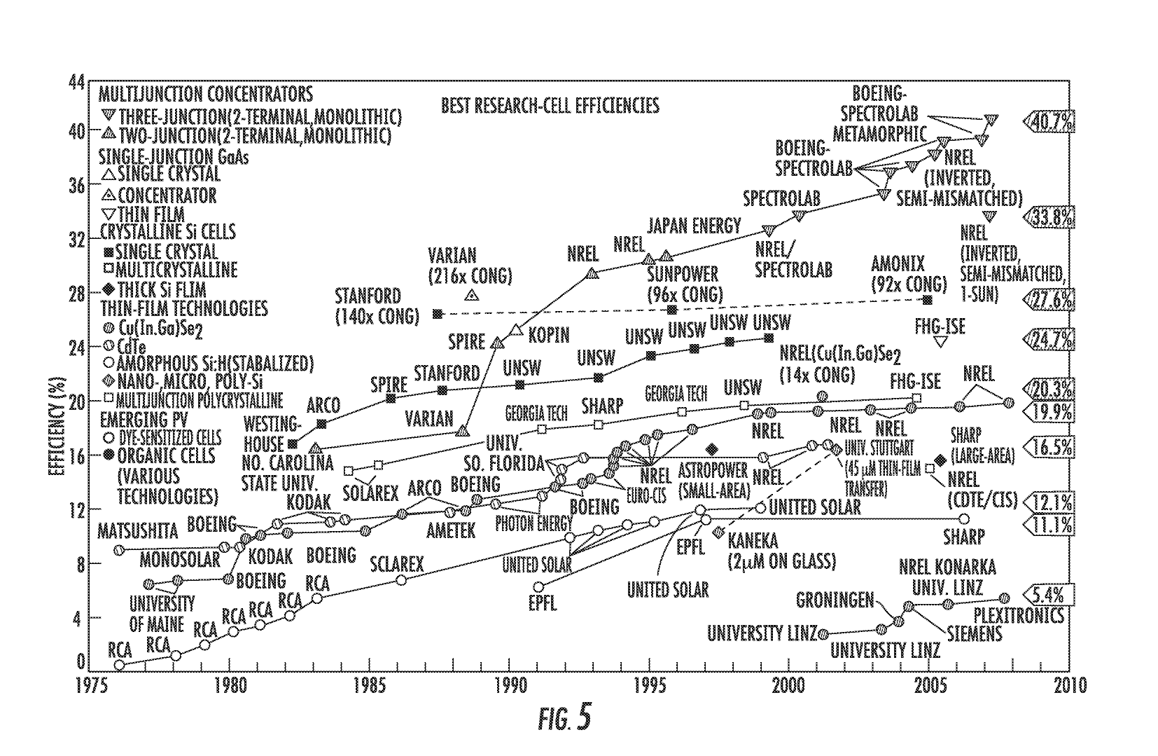

Structures were optimized with a bounding-volume of area footprint (base area) 10×10 m² and height ranging from 2 to 10 m. FIG. 6 shows the energy generated in a day as a function of the height of the GA-optimized 3DPV solar cell, compared to that of a flat panel of same area footprint. The generated energy of the 3D structures scales linearly with height, thus leading to “volumetric” energy conversion. In addition, the power generated as a function of time during the day (inset, FIG. 3) shows a much more even distribution for 3DPV, due to the availability of cells with different orientations within the structure. The increase in power with height is dominant in the early morning and late afternoon, as expected, although the enhancement is broad in time and remains significant at all times during the day, even at midday. This even supply of power throughout the day can be “built-in” to a 3D structure, in contrast to power generated by a flat panel, which, without dual-axis tracking, decays rapidly around peak-time.

Interestingly, all the GA structures generated in example 1 show similar patterns in their shapes, even for different heights. They contain no holes running across the bounding volume. This may be useful to intercept most of the incoming sunlight. Less intuitively, GA structures generated in example 1 have triangles coinciding with the twelve edges of the bounding box volume, so that they would cast the same shadow on the ground as the open-box. These patterns emerge from randomly generated structures, are not artifacts of the simulations, and are a fingerprint of emergent behavior resulting from the GA calculations. See M. Mitchell, Complexity: A Guided Tour (Oxford University Press, USA, 2009), which is incorporated herein by reference as if fully set forth. The primary shape of the GA structure (FIG. 2) was a box with its five visible faces caved in towards the midpoint. A simplified, symmetric version of this was constructed and is shown in FIG. 1; this idealized structure, which is referred to as the “funnel” in this example, generates only 0.03% less energy in the day than the original GA output, and therefore contains most key ingredients of the complicated GA structures.

The energy generated was compared by simple openbox shapes and the funnel structures through a figure of merit M, defined as the ratio of the energy produced in a day to the total area of active material used, and scaled to 1 for the flat panel case. Table 1, below, presents the Energy produced in a day (E_{box}, E_{funnel}) relative to the flat panel (E₀) for the 3D open box and funnel structures, and corresponding figures of merit (M_{box}, M_{funnel}) for an area footprint of 10×10 m². As can be seen in Table 1, the energy of the funnel shape outperforms the open-box at all heights, and while both structures generate more energy than the flat panel case, they use excess material for a given energy (i.e., M<1). For example, for a height of 10 m the open-box shape generates approximately 2.38× as much energy as the flat panel but requires 9× as much active material (M=0.26). The figure of merit for the open box decreases with height indicating that such a shape is not ideal for 3DPV in terms of efficient materials use. On the other hand, the GA-derived funnel shapes maintain a nearly constant figure of merit over this height range, with a cross-over to superior materials performance compared to the open-box at a height of ˜5 m, and 30% higher M at 10 m.

TABLE 1

| Height | EBox/E₀ | E_{Funnel}/E₀ | M_{Box} | M_{Funnel} |
|---|---|---|---|---|
| 2 | 1.29 | 1.29 | 0.49 | 0.36 |
| 4 | 1.56 | 1.58 | 0.37 | 0.36 |
| 6 | 1.83 | 1.87 | 0.32 | 0.36 |
| 8 | 2.11 | 2.15 | 0.29 | 0.35 |
| 10 | 2.38 | 2.43 | 0.26 | 0.34 |

Despite the relatively small increase in energy generation of the GA shapes compared to the open box, these structures shed light on some fascinating aspects of 3DPV and may give significant practical advantages. The increase in produced energy of the best-performing GA structures is due to a decrease in the total power reflected to the environment and an increase in power generated using light reflected from other cells. This was seen by first disallowing the absorption of reflected rays, which resulted in a loss of roughly half of the increase in energy production. The remaining difference was eliminated if reflections are completely disabled (case R=0), in which case the open-box and GA structures generate the same energy to within 0.005% agreement.

### Example 2

### Three-Dimensional Photovoltaic Device Shape and Optimization with Variable Reflectance

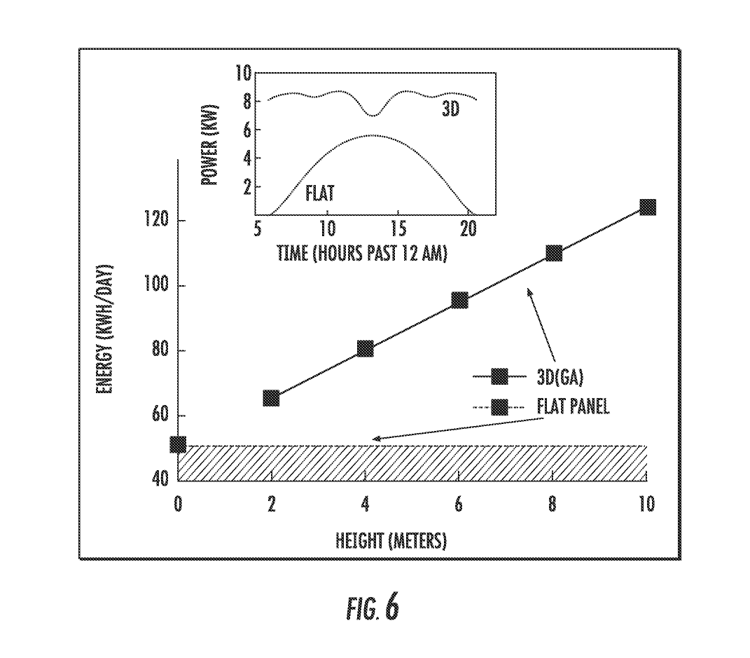

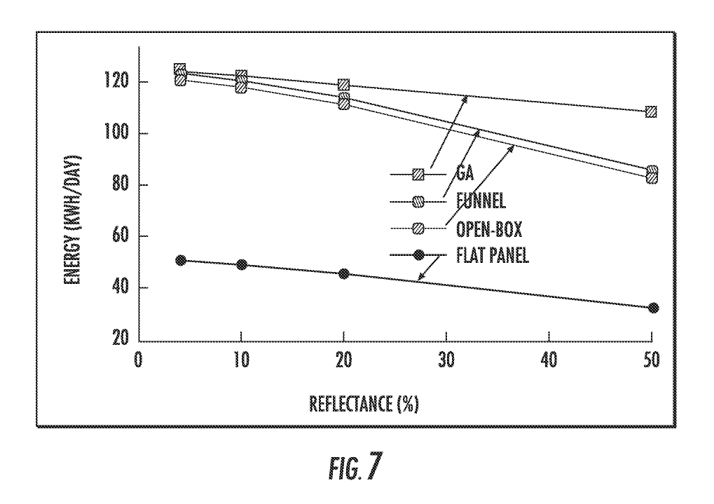

It was also investigated how significant changes in reflectance might alter the optimal results. A 3D architecture could be optimized to capture light using multiple reflections while preventing shading of the active material, possibly limiting the need for expensive antireflective coatings (See R. W. Miles, G. Zoppi, and I. Forbes, Mater. Today 10, 20 (2007), which is incorporated herein by reference as if fully set forth). A discussion of inter-cell reflections in solar cell technological reality can be found in P. R. Sharps, “Dual Sided Photovoltaic Package,” U.S. Patent Application 20090223554 (2009), which is incorporated herein by reference as if fully set forth. This example varied the reflectivity in the simulations of example 1 using R=4.1%, 10%, 20%, and 50% for a fixed volume of 10×10×10 m³ for all the shapes considered above, and performed separate GA optimizations for each value of R. FIG. 7 shows that the performance decreases linearly in all cases for increasing reflectivity, but with a much slower rate for the GA optimized structures than in all other cases. These trends indicate that for 3D solar cells it is possible to optimize the shapes such that materials within a relatively wide reflectance range can be used without significant deterioration of their performance, in contrast with current flat panel technology, deriving from intricate inter-cell coupling through reflection and re-absorption in 3DPV.

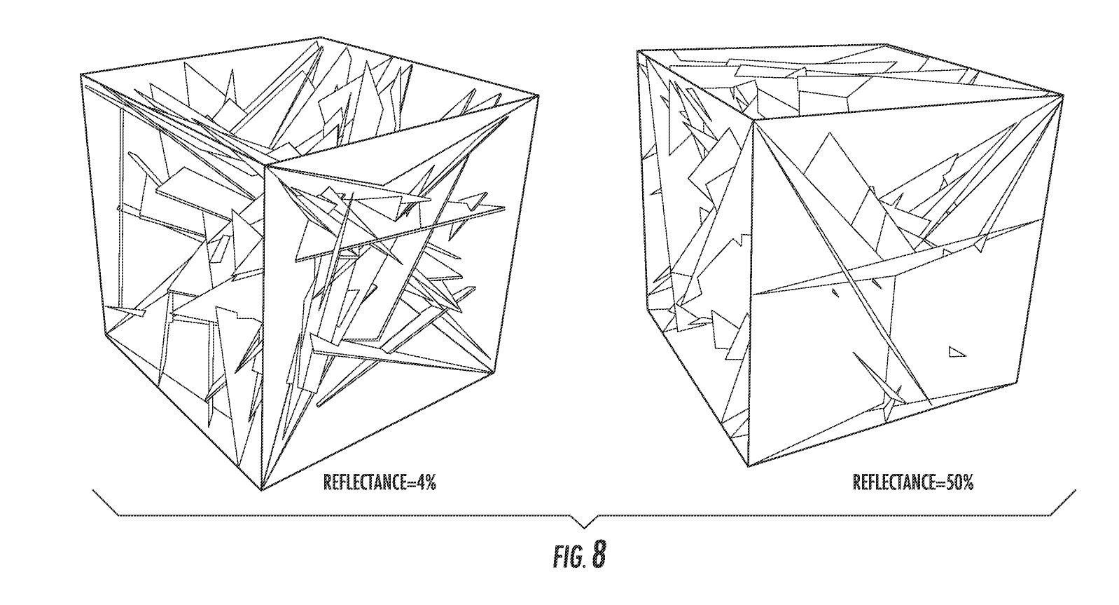

FIG. 8 illustrates two optimized structures, one three-dimensional photovoltaic device optimized as above and using a reflectance, R,=4% and one using a reflectance, R,=50%. The following points are noted in the comparison of these two optimized structures:
1) the genetic algorithm optimization approach described herein is clearly able to find shapes that lose little performance with dramatically varying reflectance values;
2) as reflectance increase the shapes appear to have introduced asymmetries in how shallow the sides become;
3) the changes in shapes with increased R appears to depend on orientation and global position; and
4) increasing R appears to change the shape on the top parts to contain more vertically-oriented panels.

Parameters other than or in addition to R may be varied. For example, h could be varied.

Examples 1 and 2 show that 3DPV structures may provide substantially more energy in a day than flat panels of the same area footprint, and that shapes optimized using a GA approach may allow for significant materials saving and also the use of materials within a wide reflectance range without degradation of the device performance.

### Example 3

### Power Conversion Considerations

The assembly of 3DPV architectures and the creation of 3D electrical connections may be conducted as known in the art. In addition, the following example power conversion architectures are provided.

In a typical 1-D solar panel, a number of cells (typically in the range of 12-96 cells) are connected in series, such that the low voltages generated by individual solar cells can be added to provide a higher-voltage panel output. To provide connection to the ac power grid, a number of power conversion architectures have been utilized. For example power conversion architectures, see S. B. Kjaer, J. K. Pedersen, and F. Blaabjerg, “A review of single-phase grid-connected inverters for photovoltaic modules,” IEEE Transactions on Industry Applications, 41(5):1292-1306, 2005; Quan Li and P. Wolfs, “A review of the single phase photovoltaic module integrated converter topologies with three different dc link configurations,” IEEE Transactions on Power Electronics, 23(3):1320-1333, 2008; J. M. A. Myrzik and M. Calais, “String and module integrated inverters for single-phase grid connected photovoltaic systems—a review,” In Proc. IEEE Bologna Power Tech, June 2003; P. J. Wolfs and L. Tang, “A single cell maximum power point tracking converter without a current sensor for high performance vehicle solar arrays,” IEEE Power Electronics Specialists Conference, pages 165-171, 2005; G. R. Walker and P. C. Sernia, “Cascaded DC-DC Converter Connection of Photovoltaic Modules,” IEEE Transactions on Power Electronics, 19(4):1130-1139, 2004; A. Woyte, J. Nijs, and R. Belmans “Partial shadowing of photovoltaic arrays with different system configurations: literature review and field test results,” Solar Energy, 74:217-233, 2003; R. W. Erickson and A. P. Rogers, “A Microinverter for Building-Integrated Photovoltaics,” 2009 Applied Power Electronics Conference, pages 911-917, 2009; and D. P. Hohm and M. E. Ropp, “Comparative Study of Maximum Power Point Tracking Algorithms,” Progress in Potovoltaics: Research and Applications, 11: 47-62, 2003, which are all incorporated herein by reference as if fully set forth. Power conversion architectures known in the art, including those in the references incorporated above may be used in a three-dimensional photovoltaic device and systems incorporating three-dimensional photovoltaic devices. Power conversion architectures include but are not limited to:
Connection of panels (or cells) in series to build up a sufficiently high voltage to feed a centralized dc-ac inverter;
Use of individual “panel-level” or “module-level” dc-ac inverters with high transformation ratio (“module-integrated converters”);
Providing individual dc-dc converters for each panel, with the converter outputs connected in parallel to deliver the energy from the panels to a high-voltage dc bus. This bus can then be connected to the grid through a centralized dc-ac converter; and
Cascaded dc-dc converter connection of photovoltaic modules with outputs connected in series to deliver energy to a high-voltage inverter.

The approaches described above work well when the cells in an individual series- or parallel-connected group (e.g., a panel) are matched and receive similar insolation. Partial shading of such a group can greatly decrease the output power capability of the whole system (e.g., see A. Woyte et al.). Consider the common case of a series-connected group. All of the cells in a series-connected group must share the same current, which cannot match the ideal current for maximum power point (MPP) operation of each cell when there is unequal insolation of the cells. This is a moderate problem in conventional 1-D panels (which is addressed through conversion architecture as described in the references cited above), it is also a consideration in the 3DPV architecture. This is because there may be wide variation in insolation of individual sections of the 3DPV structure at any given time, and that the variations may depend on the time of day and possibly other factors.

Power conversion architectures that are matched to a 3DPV architecture are provided in this example. In each of these architectures, the 3DPV structure is broken down into individual zones (portions of the surface) each of which are expected to receive relatively uniform insolation across the zone at a given point in time. Each of these zones is populated with one of: an individual solar cell, a group of series-connected solar cells (perhaps with back diodes or bypass transistors within the group), or a group of parallel-connected cells (perhaps with or-ing diodes or transistors within the group). Hereafter, one of these sub-units (i.e., an individual solar cell, a group of series connected solar cells, or a group of parallel-connected solar cells) is referred to as a “group.”

In a possible architecture, each group (covering a zone) is connected to the input of a dc-dc power converter (e.g., a buck converter, boost converter, flyback converter, a Cuk converter, a SEPIC converter, a Zeta converter etc.), the outputs of which feed a common bus. The individual converters can then provide maximum power point tracking of the individual groups (See D. P. Hohm and M. E. Ropp), and feed the extracted energy into the common output. (Additional constraints on the MPPT controls may be utilized to limit energy extraction such that the common output is maintained within an acceptable voltage range.) This common output may then be treated at the system level in a fashion similar to the way one would treat an individual panel (e.g., connected to a module-integrated inverter or others of the architectures in S. B. Kjaer et al., Quan Li and P. Wolfs, J. M. A. Myrzik and M. Calais, P. J. Wolfs and L. Tang, G. R. Walker and P. C. Sernia, A. Woyte et al., and R. W. Erickson and A. P. Rogers). The efficiency penalty of the converters for individual groups (e.g., ˜5% of extracted energy) is small compared to the benefit that the 3DPV system brings in terms of additional energy extracted. It should be noted that the selection of the common output voltage range (e.g., similar to that of a typical 1D panel, or boosted up to a higher voltage for simpler dc-ac inversion) may depend on the size and configuration of the 3DPV structure, and the granularity and configuration with which the individual zones are formed. Selection of a power converter topology may likewise depend on the common output voltage, the level of granularity of the zones and the configuration of the group structures, and whether or not galvanic isolation of the common output from the individual group connections is desired. Higher voltage outputs will favor topologies such as boost, tapped-inductor boost, and flyback conversion. Desire for isolation would necessitate an isolated converter structure. This architecture has particular advantage when one desires to endow a 3DPV structure with characteristics that are similar to those of an individual 1D module (albeit with better energy extraction per footprint area).

In a second possible architecture, individual groups may each be provided with a dc-dc converter wherein the converter outputs are connected in series (or cascade, See P. J. Wolfs and L. Tang and G. R. Walker and P. C. Sernia). As individual groups may be expected to have very different MPP power points at any given time, the converter topology should be selected so as to enable individual groups to be bypassed during time periods when they cannot deliver significant power. Delivering significant power, in an example, refers to delivering a power level sufficiently high that the net power delivered to the system output increases by including the group. Power converters such as buck converters and synchronous buck converters are suitable for this (See, for example, G. R. Walker and P. C. Sernia). The series string can then be connected to a single dc-ac inverter to provide grid interface (See, for example, A. Woyte).

A third possible architecture is a hybrid of the first two. Subsets of groups can be “converter paralleled” as in the first architecture, and these parallel groups can then be series-connected to build up a higher voltage as in the second architecture. It would be advantageous to select the groups in a subset such that each parallel group is expected to deliver approximately constant total power over the course of a day (for a given level of insolation). In this manner, the paralleled groups are more nearly matched in power, such that less control is required to maximize power delivery from the series connection of subsets.

A final architecture is to provide each group with its own individual inverter (or microinverter). This is similar to treating each group (or zone) as a separate panel in a conventional 1-D array of panels. This architecture is desirable for particularly large structures where individual groups comprise many series-connected cells, such that direct dc-ac conversion of the power from an individual group is practical.

### REFERENCES

Ginley, and M. A. Green, R. Collins, MRS Bulletin 33, 355 (2008).
W. Miles, G. Zoppi, and I. Forbes, Mater. Today 10, 20 (2007).
C. Mayer, S. R. Scully, B. E. Hardin, M. W. Rowell, and M. D. McGehee, Mater. Today 10, 28 (2007).
4G. Conibeer, Mater. Today 10, 42 (2007).
A. Green, Third Generation Photovoltaics: Advanced Solar Energy Conversion (Springer 2005).
S. Arunachalam and E. L. Fleischer, MRS Bulletin 33, 264 (2008).
7J. Nelson, The Physics of Solar Cells (Imperial College Press, 2003).
H. Park, S. Roy, S. Beaupré, S. Cho, N. Coates, J. S. Moon, D. Moses, M. Leclerc, K. Lee, and A. J. Heeger, Nature Photonics 3, 297 (2009).
M. Swanson, Prog. Photovolt.: Res. Appl. 14, 443 (2006).
H. Gracias, J. Tien, T. L. Breen, C. Hsu, and G. M. Whitesides, Science 289, 1170 (2000); M. Boncheva, S. A. Andreev, L. Mahadevan, A. Winkleman, D. R. Reichman, M. G. Prentiss, S. Whitesides, and G. M. Whitesides, PNAS 102, 3924 (2005).
Fthenakis, Renewable and Sustainable Energy Reviews 13, 2746 (2009).
For an introduction to the genetic algorithm approach, see D. E. Goldberg, Genetic Algorithms in Search, Optimization, and Machine Learning (Addison-Wesley Professional, 1989).
Kumara, Single and Multiobjective Genetic Algorithm Toolbox in C++ (Illinois) Genetic Algorithms Laboratory, Report No. 2007016, 2007.

The single-objective version was used in our simulations.
L. Miller, and D. E. Goldberg, Evolutionary Computation 4, 113 (1996).
Reda, and A. Andreas, Solar Energy 76, 577 (2004).
Mitchell, Complexity: A Guided Tour (Oxford University Press, USA, 2009).
P. R. Sharps, “Dual Sided Photovoltaic Package,” U.S. Patent Application 20090223554 (2009).
S. B. Kjaer, J. K. Pedersen, and F. Blaabjerg, “A review of single-phase grid-connected inverters for photovoltaic modules,” IEEE Transactions on Industry Applications, 41(5):1292-1306, 2005.
Quan Li and P. Wolfs, “A review of the single phase photovoltaic module integrated converter topologies with three different dc link configurations,” IEEE Transactions on Power Electronics, 23(3):1320-1333, 2008.
J. M. A. Myrzik and M. Calais, “String and module integrated inverters for single-phase grid connected photovoltaic systems—a review,” In Proc. IEEE Bologna Power Tech, June 2003.
P. J. Wolfs and L. Tang, “A single cell maximum power point tracking converter without a current sensor for high performance vehicle solar arrays,” IEEE Power Electronics Specialists Conference, pages 165-171, 2005.
G. R. Walker and P. C. Sernia, “Cascaded DC-DC Converter Connection of Photovoltaic Modules, “IEEE Transactions on Power Electronics, 19(4):1130-1139, 2004.
A. Woyte, J. Nijs, and R. Belmans “Partial shadowing of photovoltaic arrays with different system configurations: literature review and field test results,” Solar Energy, 74:217-233, 2003.
R. W. Erickson and A. P. Rogers, “A Microinverter for Building-Integrated Photovoltaics,” 2009 Applied Power Electronics Conference, pages 911-917, 2009.
D. P. Hohm and M. E. Ropp, “Comparative Study of Maximum Power Point Tracking Algorithms,” Progress in Potovoltaics: Research and Applications, 11: 47-62, 2003.

The references cited throughout this application, are incorporated for all purposes apparent herein and in the references themselves as if each reference was fully set forth. For the sake of presentation, specific ones of these references are cited at particular locations herein. A citation of a reference at a particular location indicates a manner(s) in which the teachings of the reference are incorporated. However, a citation of a reference at a particular location does not limit the manner in which all of the teachings of the cited reference are incorporated for all purposes.

It is understood, therefore, that this invention is not limited to the particular embodiments disclosed, but is intended to cover all modifications which are within the spirit and scope of the invention as defined by the appended claims; the above description; and/or shown in the attached drawings.

What is claimed is:

1. A three-dimensional photovoltaic device comprising: one or more solar cells arranged within a volume, the one or more solar cells having a photovoltaic surface having at least one concave face and a first area and a second area, wherein the first area is configured to reflect light to the second area.

2. The device of claim 1, wherein the photoelectric surface is continuous over one or more of the at least one concave face.

3. The device of claim 2, wherein the device photoelectric surface is continuous over each of the at least one concave face.

4. The device of claim 1, wherein the one or more solar cells include at least one flat panel solar cell.

5. The device of claim 1, wherein the one or more solar cells include at least one double-sided flat panel solar cell.

6. The device of claim 1, wherein the volume has a height from 1 mm to 10 m, a width from 1 mm to 10 m, and a depth from 1 mm to 10 m.

7. The device of claim 1, wherein the volume has a midpoint, a height, a width and a depth, and the height is equal to the width and the depth.

8. The device of claim 7, wherein the at least one concave face includes at least four concave faces having respective centers at respective sides of the cube, and the respective centers extend toward the midpoint.

9. The device of claim 7, wherein the at least one concave face includes at least five concave faces having respective centers at respective sides of the cube, and the respective centers extend toward the midpoint.

10. The device of claim 1 further comprising one or more operably connected zones, wherein each of the one or more operably connected zones includes at least a portion of the photovoltaic surface; and
a power conversion architecture operably connecting the one or more zones to at least one power output,
wherein the photoelectric surface in a zone is configured to receive the same range of insolation levels over a given period of insolation.

11. The device of claim 1 further comprising one or more operably connected zones, wherein each of the one or more operably connected zones includes at least a portion of the photovoltaic surface; and
a power conversion architecture operably connecting the one or more zones to at least one power output,
wherein respective ones of the one or more zones include at least one of a single one of the one or more solar cells, a group of the one or more solar cells connected in series, or a group of the one or more solar cells connected in parallel.

12. The device of claim 11, wherein the power conversion architecture includes a plurality of dc-dc power converters having converter inputs and converter outputs, and each of the one or more zones is connected to a respective converter input and each converter output is connected to a common bus.

13. The device of claim 11, wherein the power conversion architecture includes a plurality of dc-dc power converters having respective converter inputs and converter outputs, and each zone is connected to a respective input; the converter outputs are connected to one another in series or cascade; and the output of the three-dimensional photovoltaic device is connected to a dc-ac inverter.

14. A system including a plurality of the devices of claim 11 operably connected through the at least one power output.

15. The system of claim 14, wherein the power conversion architecture includes a plurality of dc-dc power converters having converter inputs and converter outputs, and each of the one or more zones is connected to a respective converter input and each converter output is connected to a common bus.

16. The system of claim 14, wherein the power conversion architecture includes a plurality of dc-dc power converters having respective converter inputs and converter outputs, and each zone is connected to a respective input; the converter outputs are connected to one another in series or cascade; and the output of each of the three-dimensional photovoltaic devices is connected to a dc-ac inverter.

17. The system of claim 14, wherein the at least one power output is a dc-ac inverter and individual ones of the plurality of the three-dimensional photovoltaic devices are connected to one another through respective connections to the dc-ac inverter.

18. The system of claim 14 further comprising a substrate fixed to the at least one three-dimensional photovoltaic device.

19. The system of claim 14, wherein the substrate is selected from the group consisting of clothing, paper, rock, brick, pavement, cement and soil.

20. The system of claim 19, wherein the substrate is clothing and the volume has a height from 1 mm to 1 cm, a width from 1 mm to 1 cm, and a depth from 1 mm to 1 cm.

21. The system of claim 14, wherein at least one of the plurality of the three-dimensional photovoltaic devices fixed to a second of the plurality of the three-dimensional photovoltaic devices.

22. A method of optimizing a three-dimensional photovoltaic device comprising:
defining a plurality of devices, each of the devices including a respective plurality of solar cells having coordinates in Cartesian space, wherein each of the respective solar cells has a respective geometric shape and the respective plurality of solar cells for each of the plurality of devices are confined to a respective volume, and the respective volume includes a first face, a second face, a third face, and a fourth face;
testing the energy produced by each of the plurality of devices;
randomly selecting a set of s devices from the plurality of devices and choosing one of the devices in the set of s to proceed to a mating pool, wherein the one of the devices is chosen based on the energy of the one being higher than the energy of the devices remaining in the set of s;
reiterating the randomly selecting step until two or more of the devices are in the mating pool;
forming random pairs of the devices in the mating pool, crossing solar cell coordinates within the random pairs, and perturbing at least one coordinate of the solar cells in the random pairs;
assessing the energy production of the devices; and
repeating the testing, selecting, reiterating, forming, crossing, perturbing and assessing steps until a three-dimensional structure with maximal energy production is achieved.

23. The method of claim 22, wherein the geometric shapes are triangles.

24. The method of claim 22, wherein the number of solar cells in the respective plurality of solar cells in each respective one of the devices is in the range of 64-1,000.

25. The method of claim 22, wherein the solar cells are double-sided.

26. The method of claim 22, wherein the solar cells have a spectral-averaged power reflectance, R, and R is constant.

27. The method of claim 26, wherein R is 4.1%.

28. The method of claim 22, wherein the solar cells have a power conversion efficiency, h, and h is constant.

29. The method of claim 28, wherein h is 6%.

30. The method of claim 22, wherein the first face points east, the second face points west, the third face points north, and the fourth face points south.
